(19) United States
(12) Patent Application Publication
(10) Pub. No.: US 2012/0302048 A1
(43) Pub. Date: Nov. 29, 2012

(54) PRE OR POST-IMPLANT PLASMA TREATMENT FOR PLASMA IMMERSED ION IMPLANTATION PROCESS

(75) Inventors: Kartik Santhanam, Milpitas, CA (US); Yen B. Ta, Pomona, CA (US); Matthew D. Scotney-Castle, Morgan Hill, CA (US); Manoj Vellaikal, Sunnyvale, CA (US); Martin A. Hilkene, Gilroy, CA (US); Peter I. Porshnev, Poway, CA (US); Majeed A. Foad, Sunnyvale, CA (US)

(73) Assignee: Applied Materials, Inc., Santa Clara, CA (US)

(21) Appl. No.: 13/461,476

(22) Filed: May 1, 2012

Related U.S. Application Data
(60) Provisional application No. 61/490,917, filed on May 27, 2011.

(51) Int. Cl. H01L 21/265

(52) U.S. Cl. 438/513; 257/E21.334

(57) ABSTRACT

Methods for implanting ions into a substrate by a plasma immersion ion implanting process are provided. In one embodiment, the method for implanting ions into a substrate by a plasma immersion ion implantation process includes providing a substrate into a processing chamber, flowing a gas mixture including a hydride dopant gas and a fluorine-containing dopant gas into the processing chamber, wherein the hydride dopant gas comprises P-type hydride dopant gas, N-type hydride dopant gas, or a combination thereof, and the fluorine-containing dopant gas comprises a P-type or N-type dopant atom, generating a plasma from the gas mixture, and co-implanting ions from the gas mixture into a surface of the substrate.

### CROSS-REFERENCE TO RELATED APPLICATIONS

This application claims benefit of U.S. provisional patent application Ser. No. 61/490,917, filed May 27, 2011, which is herein incorporated by reference.

### BACKGROUND OF THE INVENTION

1. Field of the Invention

Embodiments of the invention generally relate to the field of semiconductor manufacturing processes, more particular, to methods of implanting ions into a substrate by a plasma immersion ion implantation process.

2. Description of the Related Art

Plasma immersion ion implantation is a semiconductor process typically utilized to implant ions of species into a semiconductor substrate, forming interconnect features, such as gate and source drain structure, with desired profile and concentration. The plasma may be generated using a plasma source such as a toroidal plasma source at the reactor chamber ceiling. Ion energy sufficient to achieve a desired ion implantation depth profile below the substrate surface is provided by coupling a bias voltage to the substrate through an insulated cathode electrode within the substrate support pedestal.

In DRAM/Flash Memory application, it may be necessary to implant a semiconductor dopant species into the polycrystalline silicon (polysilicon) gate electrodes to increase their conductivity. The gate electrodes are typically formed by depositing amorphous silicon on a thin gate oxide layer and then annealing the substrate sufficiently to transform the deposited silicon from the amorphous state to a polycrystalline state. The implanted species from the dopant gas promotes p-type semiconductivity in silicon, such as boron, or n-type semiconductivity, such as arsenic, phosphorous or antimony.

However, it has been observed that some plasma by-products may deposit as films on the substrate surface during the plasma immersion ion implantation process. If a dopant gas consisting of a hydride is used, some of the hydride may also deposit on the substrate surface while it is being implanted into the substrate. These plasma by-products and hydride depositions would act as a barrier which inhibits ion penetration into the substrate and unfavorably affects the desired ion implantation depth profile below the substrate surface. This is particularly true in cases like Ultra Shallow Junctions where the implantation process is carried out at a very low ion energy (low ion acceleration voltage) and therefore the ions may not obtain energy high enough to penetrate the barrier, thereby adversely influencing the overall electrical device performance.

Therefore, there is a need for an improved ion implantation process that is free of the foregoing problems.

### SUMMARY OF THE INVENTION

The present invention provides methods for implanting ions into a substrate by a plasma immersion ion implantation (Piii) process. The improved method advantageously implants higher amount of dopants into a substrate surface with minimal hydride deposition, without adversely contaminating or altering dopant ion concentration on the substrate. The improved method also prevents the fluoride species from etching a polysilicon gate and/or being co-implanted into a substrate surface while maximizes the amount of ions of a desired conductivity type implanted into the substrate, thereby forming electric devices on the substrate with desired electrical performance.

In one embodiment, a method for implanting ions into a substrate includes providing a substrate into a processing chamber, flowing a gas mixture including a hydride dopant gas and a fluorine-containing dopant gas into the processing chamber, wherein the hydride dopant gas comprises P-type hydride dopant gas, N-type hydride dopant gas, or a combination thereof, and the fluorine-containing dopant gas comprises a P-type or N-type dopant atom, generating a plasma from the gas mixture, and co-implanting ions from the gas mixture into a surface of the substrate. In one example, the P-type hydride dopant gas may include B₂H₆, B₄H₁₀, B₅H₉, B₅H₁₁, B₆H₁₀, B₆H₁₂, or B₆H₁₄. The N-type hydride dopant gas may include PH₃ or P₂H₄. The fluorine-containing dopant gas may include BF₃, PF₃, As₂F₃, AsF₅, AsF₃, PF₅, SbF₃, SbF₅, or their associated ions.

In another embodiment, a method for implanting ions into a substrate includes flowing a hydride precursor gas into a processing chamber to deposit a hydride barrier layer on a surface of a substrate disposed in the processing chamber, terminating the hydride precursor gas and flowing a fluorine-containing dopant gas into the processing chamber, wherein the fluorine-containing dopant gas comprises a P-type or N-type dopant atom, generating a plasma from the fluorine-containing dopant gas, and implanting ions from the fluorine-containing dopant gas into the hydride barrier layer deposited on the substrate. In one example, the hydride barrier layer is a P-type or N-type compound selected from the group consisting of B₂H₆, B₄H₁₀, B₅H₉, B₆H₁₁, B₆H₁₀, B₆H₁₂, B₆H₁₄, PH₃ and P₂H₄. The fluorine-containing dopant gas may include BF₃, PF₃, As₂F₃, AsF₅, AsF₃, PF₅, SbF₃, SbF₅, or their associated ions.

In yet another embodiment, a method for implanting ions into a substrate includes performing a pre-implantation plasma treatment using a fluorine-containing gas in a processing chamber to remove native oxides from a surface of the substrate, flowing a hydride dopant gas into the processing chamber while maintaining the plasma, and applying a RF bias power to a substrate support on which the substrate is placed to implant ions from the hydride dopant gas and the fluorine-containing gas into the surface of the substrate. The fluorine-containing dopant gas may include BF₃, PF₃, As₂F₃, AsF₅, AsF₃, PF_{S}, SbF₃, SbF₅, or their associated ions. The hydride dopant gas comprises a P-type or N-type compound selected from the group consisting of B₂H₆, B₄H₁₀, B₅H₉, B₆H₁₁, B₆H₁₀, B₆H₁₂, B₆H₁₄, PH₃ and P₂H₄.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B depict one embodiment of a plasma immersion ion implantation tool suitable for practice the present invention; and

FIG. 2 depicts a process flow diagram illustrating a method for plasma immersion ion implantation process according to one embodiment of the present invention.

FIG. 3 depicts a process flow diagram illustrating a method for plasma immersion ion implantation process according to another embodiment of the present invention.

FIG. 4 depicts a process flow diagram illustrating a method for plasma immersion ion implantation process according to one another embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

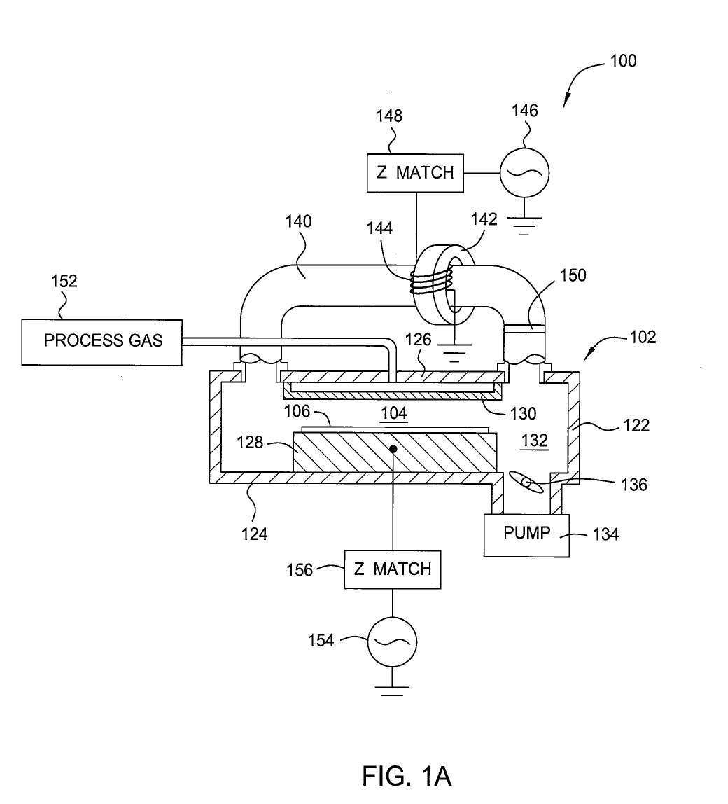

FIG. 1A depicts a processing chamber 100 that may be utilized to practice an ion implantation process according to various embodiments of the invention. One suitable processing chamber in which the process may be practiced is a P3i® reactor, available from Applied Materials, Inc., of Santa Clara, Calif. It is contemplated that the methods described herein may be practiced in other suitably adapted processing chambers, including those from other manufacturers.

The processing chamber 100 includes a chamber body 102 having a bottom 124, a top 126, and side walls 122 enclosing a process region 104. A substrate support assembly 128 is supported from the bottom 124 of the chamber body 102 and is adapted to receive a substrate 106 for processing. A gas distribution plate 130 is coupled to the top 126 of the chamber body 102 facing the substrate support assembly 128. A pumping port 132 is defined in the chamber body 102 and coupled to a vacuum pump 134. The vacuum pump 134 is coupled through a throttle valve 136 to the pumping port 132. A gas source 152 is coupled to the gas distribution plate 130 to supply gaseous precursor compounds for processes performed on the substrate 106.

The processing chamber 100 depicted in FIG. 1A further includes a plasma source 190 best shown in the perspective view of FIG. 1B. The plasma source 190 includes a pair of separate external reentrant conduits 140, 140′ mounted on the outside of the top 126 of the chamber body 102 disposed transverse to one another (or orthogonal to one another as the exemplary embodiment depicted in FIG. 1B). The first external conduit 140 has a first end 140a coupled through an opening 198 formed in the top 126 into a first side of the process region 104 in the chamber body 102. A second end 140b has an opening 196 coupled into a second side of the process region 104. The second external reentrant conduit 140b has a first end 140a′ having an opening 194 coupled into a third side of the process region 104 and a second end 140b′ having an opening 192 into a fourth side of the process region 104. In one embodiment, the first and second external reentrant conduits 140, 140′ are configured to be orthogonal to one another, thereby providing the two ends 140a, 140a′, 140b. 140b′ of each external reentrant conduits 140, 140′ disposed at about 90 degree intervals around the periphery of the top 126 of the chamber body 102. The orthogonal configuration of the external reentrant conduits 140, 140′ allows a plasma source distributed uniformly across the process region 104. It is contemplated that the first and second external reentrant conduits 140, 140′ may be configured as other distributions utilized to provide uniform plasma distribution into the process region 104.

Magnetically permeable torroidal cores 142, 142′ surround a portion of a corresponding one of the external reentrant conduits 140, 140′. The conductive coils 144, 144′ are coupled to respective RF plasma source power generators 146, 146′ through respective impedance match circuits or elements 148, 148′. Each external reentrant conduits 140, 140′ is a hollow conductive tube interrupted by an insulating annular ring 150, 150′ respectively that interrupts an otherwise continuous electrical path between the two ends 140a, 140b (and 140a′, 104b′) of the respective external reentrant conduits 140, 140′. Ion energy at the substrate surface is controlled by an RF plasma bias power generator 154 coupled to the substrate support assembly 128 through an impedance match circuit or element 156.

Referring back to FIG. 1A, process gases including gaseous compounds supplied from the process gas source 152 are introduced through the overhead gas distribution plate 130 into the process region 104. RF plasma source power generator 146 is coupled from the power applicator (e.g., cores and coils) 142, 144 to gases supplied in the conduit 140, which creates a circulating plasma current in a first closed torroidal path including the external reentrant conduit 140 and the process region 104. Also, RF source power 146′ may be coupled from the other power applicator (e.g., cores and coils) 142′, 144′ to gases in the second conduit 140′, which creates a circulating plasma current in a second closed torroidal path transverse (e.g., orthogonal) to the first torroidal path. The second torroidal path includes the second external reentrant conduit 140′ and the process region 104. The plasma currents in each of the paths oscillate (e.g., reverse direction) at the frequencies of the respective RF plasma source power generators 146, 146′, which may be the same or slightly offset from one another.

In one embodiment, the process gas source 152 provides different process gases that may be utilized to provide ions implanted to the substrate 106. Suitable examples of process gases may include B₂H₆, BF₃, SiH₄, SiF₄, PH₃, P₂H₅, PO₃, PF₃, PF₅ and CF₄, among others. The power of each plasma source power generators 146, 146′ is operated so that their combined effect efficiently dissociates the process gases supplied from the process gas source 152 and produces a desired ion flux at the surface of the substrate 106. The power of the RF plasma bias power generator 154 is controlled at a selected level at which the ion energy dissociated from the process gases may be accelerated toward the substrate surface and implanted at a desired depth below the top surface of the substrate 106 with desired ion concentration. For example, with relatively low RF power, such as less than about 50 eV, relatively low plasma ion energy may be obtained. Dissociated ions with low ion energy may be implanted at a shallow depth between about 0 Å and about 100 Å from the substrate surface. Alternatively, dissociated ions with high ion energy provided and generated from high RF power, such as higher than about 50 eV, may be implanted into the substrate having a depth substantially over 100 Å depth from the substrate surface.

The combination of the controlled RF plasma source power and RF plasma bias power dissociates ion in the gas mixture having sufficient momentum and desired ion distribution in the processing chamber 100. The ions are biased and driven toward the substrate surface, thereby implanting ions into the substrate with desired ion concentration, distribution and depth from the substrate surface. Furthermore, the controlled ion energy and different types of ion species from the supplied process gases facilitates ions implanted in the substrate 106, forming desired device structure, such as gate structure and source drain region on the substrate 106.

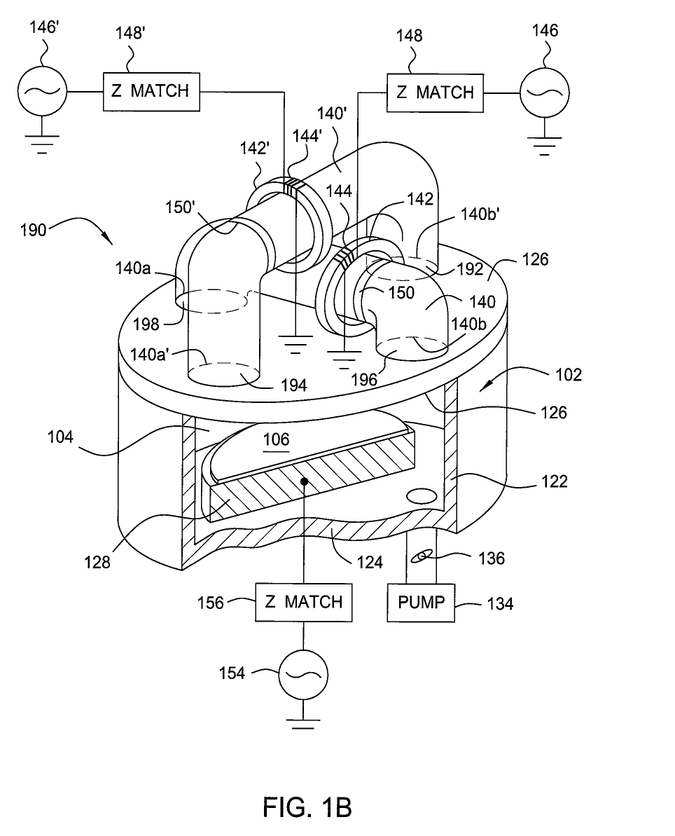

FIG. 2 depicts a process flow diagram of a method 200 for implanting ions into a substrate by a plasma immersion ion implantation process. The method 200 may be performed in a plasma immersion ion implantation processing chamber, such as the processing chamber 100 as described in FIG. 1A-1B.

The method 200 begins at step 202 by providing a substrate in the processing chamber 100. An inert gas such as Ar, He, or H₂ may be introduced into the processing chamber 100 to increase the possibility of subsequent process gas collision and/or promote the ion bombardment in the gas mixture, thereby resulting in reduced recombination of ion species. The chamber pressure is then set to strike the plasma with RF source power and maintained for following processing step. In one embodiment, the substrate may be a material such as silicon oxide, silicon carbide, crystalline silicon (e.g., Si<100> or Si<111>), strained silicon, silicon germanium, doped or undoped polysilicon, doped or undoped silicon wafers, doped silicon, germanium, gallium arsenide, gallium nitride, glass, and sapphire. The substrate may have various dimensions, such as 200 mm or 300 mm diameter wafers, as well as, rectangular or square panes. In embodiments where the substrate is utilized to form a gate structure, a polysilicon layer may be disposed on a gate dielectric layer on the substrate.

At step 204, a gas mixture is supplied into the processing chamber 100 in addition to the inert gas sustaining the plasma to provide ion species for the subsequent implantation process. The gas mixture may be supplied from the process gas source 152 to the gas distribution system 130, as described in FIG. 1A, or by other suitable means. If a P-type conductivity region is to be formed by the ion implantation in silicon, the gas mixture may include a P-type dopant gas consisting of group III elements, such as boron, aluminum, or gallium. In certain embodiments, boron may be used as the p-type dopant. In such a case, the P-type dopant gas may be a hydride, such as B₂H₆, B₄H₁₀, B₅H₉, B₅H₁₁, B₆H₁₀, B₆H₁₂, and B₆H₁₄. If an N-type conductivity region is desired, then the gas mixture may include an N-type dopant gas consisting of group V elements, such as phosphorus, arsenic, or antimony. In certain embodiments, phosphorus may be used as the n-type dopant. In such a case, the N-type dopant gas may be a hydride such as PH₃, P₂H₄ etc.

Typically, the most common precursor used for the P-type dopant gas is boron trifluoride (BF₃) due to its ability to achieve higher dose rate and lower sheet resistance. The use of BF₃ precursor also does not generate a lot of particles during plasma implantation process. However, in some applications where a polysilicon doping process is needed, BF₃ precursor dissociates into boron ions and into fluoride species including atomic fluorine during the process. The dissociated fluoride species tend to etch away the polysilicon gate layer at very high rate, which results in non-uniformity of the polysilicon gate layer and unacceptable poly loss in polysilicon gate thickness.

It has been found that etching of the polysilicon gate layer can be avoided almost entirely by employing a hydride of the desired dopant species and a fluorine-containing dopant gas as the process gas for plasma immersion ion implantation. The fluorine-containing dopant gas may be a chemical compound containing a desired conductivity type of dopant atom. For example, the fluorine-containing dopant gas may include, but is not limited to AsF₃, As₂F₃, AsF₅, PF₃, PF₅, SbF₃, SbF₅, BF₃, and their associated ions. In cases where a P-type hydride dopant gas, for example, B₂H₆, is used, the fluorine-containing dopant gas may include BF₃. In one exemplary example where a P-type conductivity region is desired in silicon, the gas mixture supplied into the processing chamber 100 may include BF₃ and B₂H₆. The BF₃ and B₂H₆ are dissociated as ion species by the plasma in form of B³⁺, BF²⁺, BF₂²⁺, F⁻, BₓH_{y}, and H⁺. The active H species provided from the B₂H₆ gas reacts with the F species and other dissociated byproducts, forming HF or other types of volatile species which can be easily pumped out of the processing chamber, thus preventing the fluoride species from etching the polysilicon gate and/or being co-implanted into the substrate in the subsequent implantation process while maximizing the amount of ions of a desired conductivity type (e.g., boron ions) to be implanted into the substrate. It has been observed that the process as described is able to achieve an ion implantation dose density of about 1E15 to about 1E19 atoms/cm². It should be noted that the target dose can be adjusted by varying implant time, pressure and implant energy to adjust for a right process window. This process can also be extended to low dose applications such as Ultra Shallow Junctions.

While not discussed in detail here, a hydrogen-containing gas such as H₂, SiH₄, NH₃, or the like, and/or a nitrogen-containing gas such as N₂, NO, NO₂, N₂O, NH₃, or the like, may be optionally added to react with the polymer gas BₓH_{y} to form a volatile gas that is also readily pumped out of the chamber, thereby preventing the polymer gas from depositing on the substrate and adversely affecting the device structure.

At step 206, the inert gas may be switched off and a plasma immersion ion implantation process is performed to implant ions generated from the gas mixture at step 204 into the substrate. A RF source power is applied to generate a plasma from the gas mixture in the processing chamber 100. The generated plasma dissociates the gas mixture in the chamber 100 as ion species. A RF bias power may be applied to the substrate support along with the RF source power to dissociate and drive the dissociated ion species from the gas mixture toward and into the substrate with a desired depth and concentration. After the implantation process, the RF bias power is turned off and an inert gas may be introduced into the processing chamber 100 while the plasma is on. Thereafter, the gas mixture is switched off and the charge on the substrate is drained in the presence of plasma by pulsing the electrostatic chuck. The substrate is then removed from the processing chamber 100.

In one embodiment, the BF₃ gas and the B₂H₆ gas may have a flow rate ratio between about 1:1 and about 1:30. Alternatively, the BF₃ gas flow rate may be supplied between 10 sccm and 1200 sccm, such as 300 sccm and the B₂H₆ gas may be supplied between 5 sccm and 50 sccm. The source RF power may be controlled at between about 100 Watts and between about 2000 Watts and the bias RF voltage may be controlled at between about 100 Volts and between about 12000 Volts. The chamber pressure during the plasma immersion ion implantation process may be maintained at between about 4 mTorr and about 500 mTorr. The substrate temperature may be maintained at between about 25 degrees Celsius and about 400 degrees Celsius.

It should be understood that the similar concept is also applicable to cases where an N-type conductivity region is to be formed by the ion implantation in silicon. For example, the mixture supplied into the processing chamber 100 may include a phosphorous hydride such as PH₃ and a fluorine-containing dopant gas such as PF₃. The active H species provided from the PH₃ gas reacts with the F species and other dissociated byproducts, forming HF or other types of volatile species which are pumped out of the chamber, thus preventing the F species from etching the polysilicon gate and/or being co-implanted into the substrate in a subsequent implantation process while maximizing the amount of ions of a desired conductivity type (e.g., phosphorous ions) to be implanted into the substrate. Similarly, in cases where hydrides such as B₂H₆ and PH₃ are to be co-implanted into the substrate, a fluorine-containing gas such as BF₃ or PF₃ may be introduced into the processing chamber to prevent undesired surface film deposition formed by B₂H₆ and PH₃ hydrides (this deposition becomes denser and difficult to remove once the substrate is subjected to annealing) while maximize the amount of boron and phosphorous ions to be implanted into the substrate.

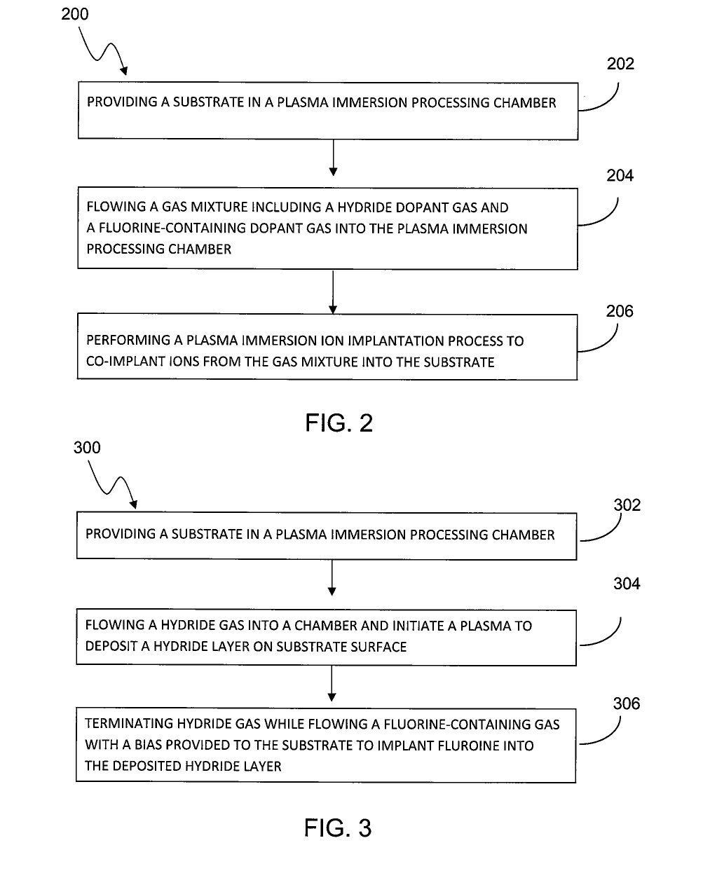

FIG. 3 depicts another embodiment of the present invention illustrating a process flow diagram of a method 300 for implanting ions into a substrate by a plasma immersion ion implantation process. This method 300 has found to be useful in preventing etching of the polysilicon gate layer due to F species as discussed above. The method 300 may be performed in a plasma immersion ion implantation processing chamber, such as the processing chamber 100 as described in FIG. 1A-1B.

The method 300 begins at step 302 by providing a substrate in the processing chamber 100. The substrate used at step 302 may be similar to step 202. In embodiments where the substrate is utilized to form a gate structure, a polysilicon layer may be disposed on a gate dielectric layer on the substrate.

At step 304, in cases where a P-type conductivity region is to be formed by the ion implantation in polysilicon layer, a P-type hydride dopant gas, for example, B₂H₆, may be introduced into the processing chamber in addition to the inert gas sustaining the plasma to deposit a B₂H₆ layer on the surface of the substrate prior to implantation. Once the plasma is stable, the inert gas may be switched off. The deposited B₂H₆ layer may act as a barrier to etching of the polysilicon gate layer due to F species. During the B₂H₆ deposition at step 304, the RF bias may not be required and a RF source power is applied at an appropriate chamber pressure to generate a plasma from the hydride dopant gas in the processing chamber 100, allowing deposition of B₂H₆ layer on the surface of the substrate until a target thickness is reached.

At step 306, once the target thickness has reached, the flow of the hydride dopant gas, for example, B₂H₆, is terminated and a fluorine-containing gas may be introduced into the processing chamber 100. The RF power may be on during the transition switching from the hydride dopant gas to the fluorine-containing gas. The fluorine-containing dopant gas may be a chemical compound containing a desired conductivity type of dopant atom. For example, the fluorine-containing dopant gas may include, but is not limited to AsF₃, As₂F₃, AsF₅, PF₃, PF_{S}, SbF₃, SbF₅, BF₃, and their associated ions. In cases where a boron hydride such as B₂H₆ is used, the fluorine-containing dopant gas may be BF₃. Once the plasma is stable, the RF bias is applied to the substrate support along with the RF source power to dissociate and drive the dissociated ion species from the fluorine-containing gas toward and into the deposited B₂H₆ layer. The implanted F species provided from the ionized BF₃ gas may react with the hydrogen atom in the deposited B₂H₆ layer, forming HF or other types of volatile species which can be pumped out of the chamber. By depositing a B₂H₆ layer on the surface of the substrate followed by F implantation, etching of the polysilicon gate layer due to F species is avoided and the P-type conductivity region is formed with a desired depth and concentration.

After the implantation process, the RF bias power is turned off and an inert gas may be introduced into the processing chamber 100 while the plasma is on. Thereafter, the fluorine-containing gas is switched off and the charge on the substrate is drained in the presence of plasma by pulsing the electrostatic chuck. The substrate is then removed from the processing chamber 100.

In one embodiment, the hydride dopant gas may be flowed into the processing chamber between about 5 sccm and about 200 sccm during the hydride deposition process for about 3 seconds to about 100 seconds to deposit a hydride layer of about 20 Å to about 500 Å. The fluorine-containing gas may be flowed into the processing chamber between about 25 sccm and about 400 sccm. The chamber pressure may be between about 4 mTorr and about 500 mTorr. The source RF power may be controlled at between about 100 Volts and between about 2000 Volts and the bias RF voltage may be controlled at between about 100 Volts and between about 12000 Volts.

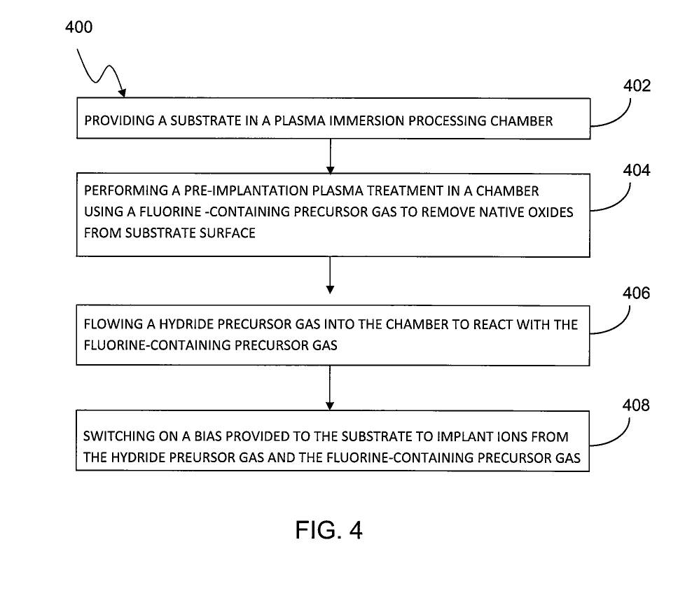

FIG. 4 depicts one another embodiment of the present invention illustrating a process flow diagram of a method 400 for implanting ions into a substrate by a plasma immersion ion implantation process. The method 400 has found to be useful in obtaining high implant doses with minimal hydride deposition on the substrate surface. As discussed above, hydride depositions would act as a barrier which unfavorably affects the desired ion implantation depth profile below the substrate surface or even inhibits implantation of ions into the substrate, especially in applications such as Ultra Shallow Junctions (i.e., junctions having source/drain regions no more than about 50 nm thick) where the implantation process is carried out at a very low ion energy (low ion acceleration voltage) so that the ions may not obtain energy high enough to penetrate the barrier. The method 400 may be performed in a plasma immersion ion implantation processing chamber, such as the processing chamber 100 as described in FIG. 1A-1B.

The method 400 begins at step 402 by providing a substrate in the processing chamber 100. The substrate used at step 402 may be similar to step 202. In embodiments where the substrate is utilized to form a gate structure, a polysilicon layer may be disposed on a gate dielectric layer on the substrate.

At step 404, a pre-implantation plasma treatment using a fluorine-containing gas is performed in the processing chamber 100. The pre-implantation plasma treatment is configured to remove native oxides (e.g., SiO₂) and other impurities from the surface of the substrate which may adversely affects the subsequent ion implantation process while also creates a fluorine ambient to make the process environment more efficient for implantation with the hydride dopant gas. The fluorine-containing dopant gas may be a chemical compound containing a desired conductivity type of dopant atom. For example, the fluorine-containing dopant gas may include, but is not limited to AsF₃, As₂F₃, AsF₅, PF₃, PF_{S}, SbF₃, SbF₅, BF₃, and their associated ions. In certain embodiments, a H₂ gas may be flown into the processing chamber in addition to the inert gas sustaining the plasma. The native oxides is removed by fluorine to form SiF₄ or with H₂ to form SiH4 in the plasma. In cases where a P-type hydride dopant gas, for example, B₂H₆, is to be used in the subsequent ion implantation process, the fluorine-containing dopant gas may be BF₃. In case where an N-type hydride dopant gas, for example, PH₃ or AsH₃ is used in the subsequent ion implantation process, the fluorine-containing dopant gas may include PF₃ (for PH₃) or As₂F3 (for AsH₃). Once the plasma is stable, the inert gas may be switched off.

At step 406, a hydride dopant gas may be introduced into the processing chamber 100 (with RF source power on) to react with the fluorine-containing dopant gas previously existed in the processing chamber 100. An inert gas may be additionally introduced into the processing chamber 100 while the plasma is on. In cases where a boron hydride such as B₂H₆ is used, the generated plasma dissociates B₂H₆ gas as ion species in form of BH²⁺, BH²⁺ and H⁺ ions, which may efficiently react with F species from the fluorine ambient and/or other by-products, forming HF or other type of volatile species which can be easily pumped out of the processing chamber 100, resulting in more boron ions to be implanted into the substrate in the subsequent ion implantation process.

At step 408, a RF bias power is applied to the substrate support on which the substrate is placed to drive the dissociated ion species, for example, boron ions, in the processing chamber 100 toward and into the substrate until a desired depth and concentration are achieved. Thereafter, the hydride dopant gas is switched off and the charge on the substrate is drained in the presence of plasma by pulsing the electrostatic chuck. The substrate is then removed from the processing chamber 100. It has been observed that the process as described is able to achieve an ion implantation dose density of about 1E15 to about 1E19 atoms/cm², which is much higher than a regular process without a pre-implantation plasma treatment. Low sheet resistance can thus be obtained by an increase in ion implantation dose. It should be noted that the target dose can be adjusted by varying implant time, pressure and implant energy to adjust for a right process window.

In one embodiment, the fluorine-containing gas may be flowed into the processing chamber between about 20 sccm and about 400 sccm during the pre-implantation plasma treatment to remove native oxides. The hydride dopant gas may be flowed into the processing chamber at a rate of between about 20 sccm and about 1000 sccm, which can also be used as a pre-implant treatment in the plasma to remove native oxides. The source RF power may be controlled at between about 100 Volts and between about 2000 Volts.

Thus, methods for implanting ions into a substrate by a plasma immersion ion implanting process are provided. The improved method advantageously implants higher amount of dopants into a substrate surface with minimal hydride deposition, without adversely contaminating or altering dopant ion concentration on the substrate. The improved method also prevents the fluoride species from etching a polysilicon gate and/or being co-implanted into a substrate surface while maximizes the amount of ions of a desired conductivity type implanted into the substrate, thereby forming electric devices on the substrate with desired electrical performance.

While the foregoing is directed to embodiments of the present invention, other and further embodiments of the invention may be devised without departing from the basic scope thereof, and the scope thereof is determined by the claims that follow.

What is claimed:

1. A method for implanting ions into a substrate, comprising:
providing a substrate into a processing chamber;
flowing a gas mixture including a hydride dopant gas and a fluorine-containing dopant gas into the processing chamber, wherein the fluorine-containing dopant gas comprises a P-type or N-type dopant atom;
generating a plasma from the gas mixture; and
co-implanting ions from the gas mixture into a surface of the substrate.

2. The method of claim 1, wherein the hydride dopant gas comprises P-type hydride dopant gas, N-type hydride dopant gas, or a combination thereof.

3. The method of claim 2, wherein the P-type hydride dopant gas comprises B₂H₆, B₄H₁₀, B₅H₉, B₅H₁₁, B₆H₁₀, B₆H₁₂, or B₆H₁₄.

4. The method of claim 2, wherein the N-type hydride dopant gas comprises PH₃ or P₂H₄.

5. The method of claim 1, wherein the fluorine-containing dopant gas comprises BF₃, PF₃, As₂F₃, AsF₅, AsF₃, PF₅, SbF₃, SbF₅, or their associated ions.

6. The method of claim 5, wherein the hydrogen-containing gas comprises H₂, SiH₄, NH₃, or the like and the nitrogen containing gas comprises NO, NO₂, NH₃, N₂ or N₂O, or the like.

7. The method of claim 1, wherein the generating a plasma further comprises:
supplying a hydrogen-containing gas and/or a nitrogen containing gas with the gas mixture into the processing chamber.

8. The method of claim 1, wherein the gas mixture comprises B₂H₆, BF₃, and associated ions thereof.

9. The method of claim 1, wherein the gas mixture comprises PH₃, PF₃, and associated ions thereof.

10. The method of claim 1, wherein the gas mixture comprises B₂H₆, PH₃, BF₃, PF₃, PF₅, and associated ions thereof.

11. The method of claim 1, wherein the substrate comprises a doped or undoped polysilicon gate layer disposed thereon.

12. A method for implanting ions into a substrate, comprising:
flowing a hydride precursor gas into a processing chamber to deposit a hydride barrier layer on a surface of a substrate;
terminating the hydride precursor gas and flowing a fluorine-containing dopant gas into the processing chamber, wherein the fluorine-containing dopant gas comprises a P-type or N-type dopant atom;
generating a plasma from the fluorine-containing dopant gas; and
implanting ions from the fluorine-containing dopant gas into the hydride barrier layer deposited on the substrate.

13. The method of claim 12, wherein the hydride barrier layer is a P-type or N-type compound selected from the group consisting of B₂H₆, B₄H₁₀, B₅H₉, B₅H₁₁, B₆H₁₀, B₆H₁₂, B₆H₁₄, PH₃ and P₂H₄.

14. The method of claim 12, wherein the fluorine-containing dopant gas comprises BF₃, PF₃, As₂F₃, AsF₅, AsF₃, PF₅, SbF₃, SbF₅, or their associated ions.

15. The method of claim 12, wherein the hydride barrier layer has a thickness of about 10 Å to about 500 Å.

16. The method of claim 12, wherein the substrate comprises a doped or undoped polysilicon gate layer disposed thereon.

17. A method for implanting ions into a substrate, comprising:
flowing a fluorine-containing gas in the presence of plasma to remove native oxides from a surface of a substrate disposed in a processing chamber;
flowing a hydride dopant gas into the processing chamber while maintaining the plasma; and
applying a RF bias power to a substrate support on which the substrate is placed to implant ions from the hydride dopant gas and the fluorine-containing gas into the surface of the substrate.

18. The method of claim 17, wherein the fluorine-containing dopant gas comprises BF₃, PF₃, As₂F₃, AsF₅, AsF₃, PF₅, SbF₃, SbF₅, or their associated ions.

19. The method of claim 17, wherein the hydride dopant gas comprises a P-type or N-type compound selected from the group consisting of B₂H₆, B₄H₁₀, B₅H₉, B₅H₁₁, B₆H₁₀, B₆H₁₂, B₆H₁₄, PH₃ and P₂H₄.

20. The method of claim 17, wherein the substrate comprises a doped or undoped polysilicon gate layer disposed thereon.
